(19) United States
(12) Patent Application Publication
(10) Pub. No.: US 2025/0056749 A1
(43) Pub. Date: Feb. 13, 2025

(54) HOUSING FOR AN ELECTRICAL DEVICE HAVING A COVER

(71) Applicant: SMA Solar Technology AG, Niestetal (DE)

(72) Inventor: Steffen Müller, Kassel (DE)

(21) Appl. No.: 18/931,210

(22) Filed: Oct. 30, 2024

Related U.S. Application Data
(63) Continuation of application No. PCT/EP2023/061680, filed on May 3, 2023.

(30) Foreign Application Priority Data
May 5, 2022 (DE) 10 2022 111 105.9

(51) Int. Cl. H05K 5/00; H05K 5/06

(52) U.S. Cl. CPC H05K 5/0004; H05K 5/061

(57) ABSTRACT

A housing of an electrical device for converting electrical power has a main body with a rear wall, side walls and a cover. The cover and body define a an interior space. Components of the electrical device are arranged in the interior space. The cover is connected to the body by a cover closure that includes a fastening structure and a closure housing. The fastening structure is retained in the closure housing, which is fastened to the cover. The body includes a pin that extends from the rear wall of the housing to the cover. A connection between the cover and pin is releasable by turning the fastening structure using a guide peg of the pin and a helically encircling guide groove of the fastening structure.

### REFERENCE TO RELATED APPLICATIONS

This application is a Continuation of International Application number PCT/EP2023/061680, filed on May 3, 2023, which claims the benefit of German Application number 10 2022 111 105.9, filed on May 5, 2022. The contents of the above-referenced patent applications are hereby incorporated by reference in their entirety.

### FIELD

The disclosure relates to a housing for an electrical device for converting electrical power and to an electrical device having a corresponding housing.

### BACKGROUND

In the field of renewable energies, inverters for feeding into the grid, such as photovoltaic inverters, are generally designed for outputs of around one kilowatt or more. This also applies to battery converters which are connected to electrical storage devices and supply power to, for example, an island network. Even powers over ten kilowatts are routinely converted in an electrical device having a housing. For larger energy generation systems, the rated powers of individual electronic power devices can be in the megawatt range, wherein voltages in the kilovolt range and currents in the kilo ampere range occur. In principle, there is no upper limit to the rated power and it essentially depends on technical progress with regard to available circuit breakers, suitable topologies, achievable power density, materials and the like. In principle, the volume of the corresponding housing increases with the rated power of an electrical device, so that for very high power levels other mechanical concepts can be used, in particular control cabinets instead of housings.

A housing of such an electrical device must meet different normative requirements depending on the field of application. In particular, the housing can shield the interior of the device from its surroundings and, for example, close it in a dustproof and waterproof manner, with the result that the housing has an IP protection class according to DIN EN 60529 and/or corresponds to one of the NEMA protective classes according to NEMA Standard 250-2003. In addition, a housing may have to be able to pass further mechanical tests according to DIN and/or UL standards, for example with regard to compression, impact testing, external influences such as bird strike and/or special exposure to water.

When handling high electrical powers, extremely high energy concentrations can accumulate in a very short time. This may be desired, for example in order to use capacitors or inductors for the dynamic temporary storage of electrical energy in the context of conversion from one form of current to another. However, undesirable energy concentrations can also occur, in particular in the event of a fault, mal-operation or after unforeseeable aging processes. In these cases, electrical energy can be converted to a considerable extent into thermal and/or mechanical energy, for example by components heating up strongly and exploding, or by flammable substances accumulating within a housing, for example, due to (electro-) chemical conversion processes, and being ignited by electrical flashovers, which in themselves are harmless.

As a result, a considerable overpressure can build up in the housing, which is sealed per se, of the electrical device. In the case of a power electronics converter, which has, for example, one of the usual protection classes IP44 or IP65, the overpressure can under unfavorable circumstances also build up very quickly, for example, within a few milliseconds. However, this should not lead to the housing being destroyed in an unpredictable manner, for example by shattering uncontrollably and possibly fragments being flung out from the interior.

If the housing is not constructed with considerable material resources in such a way that it withstands any expectable overpressure, the overpressure in the interior space of the housing can be reduced by providing a relief opening. At the same time, however, in order to comply with the relevant standards, it is necessary to design the housing such that it adequately protects the interior during normal operation, offers mechanical stability against external influences and is sealed, possibly in a waterproof or even air- and dust-tight manner.

These two objectives-sufficient protection of the interior and thus of the power electronic components arranged therein from the environment during normal operation, on the one hand, and controlled provision of a sufficiently large relief opening in the event of overpressure, on the other hand—are initially functionally contrary to each other and significantly limit the available solution space. It is also important for the electrical device to be as easy to install as possible and for the interior to be accessible, for example for maintenance and repair work.

Various solutions are known from the prior art which are intended to ensure a more or less controlled and as safe as possible pressure reduction of any sudden overpressure in an otherwise sealed housing.

For example, deformable fastening elements can be mounted on the housing which are deformed when a sudden overpressure occurs in the housing and create a gap between the cover and the housing through which the overpressure can be released. Recesses can also be provided at the fastening points of the cover and housing, which allow the housing to be deformed in the event of overpressure in the interior. Furthermore, pressure relief mechanisms are known in which a pressure relief opening in the housing is closed by an external cover which is pulled inwards by a spring so that it is pushed outwards by overpressure and releases the opening. Another possibility for pressure relief is pressure relief flaps, which can swing open in the event of overpressure. However, this can lead to parts from the interior freely reaching the surrounding area.

DE 10 2019 122 812 A1 discloses a housing of an electrical device in which a cover is connected to a housing main body via a detachable fastening means. The fastening means is arranged in the geometric center of the cover and is formed by a central screw nut which can be screwed onto an outwardly extending threaded rod connected to the housing main body and thereby fixes the cover to the housing main body.

In the event of a sudden overpressure occurring in the interior of the housing, none of the known solutions provides a sufficiently large opening for pressure relief sufficiently quickly and at the same time meets the requirements mentioned above for the mechanical properties of a housing which should be suitable in particular for an electrical device for converting considerable electrical power and which enables simplified assembly of the electrical device and accessibility of the interior.

### SUMMARY

The disclosure is directed to a housing for an electrical device which has a locking system which simplifies the opening and closing of the housing, which withstands the usual environmental, usage and fault conditions of such a device, thus increasing safety, and yet enables easy assembly and accessibility of the interior.

A housing of an electrical device for converting electrical power has, in one embodiment, a main body with a rear wall and side walls and a cover. The cover closes the main body, creating a closed interior space. Electrical and electronic components of the electrical device are arranged in the interior space of the housing. The cover is connected to the main body by means of a detachable cover closure. The cover closure comprises a fastening structure and a closure housing, wherein the fastening structure is rotatably and axially non-displaceably retained in the closure housing. The closure housing is moreover fastened to the cover in the geometric center of the cover. The main body comprises a pin which extends from the rear wall of the housing to the geometric center of the cover. A connection between the cover and the pin that is releasable by turning the fastening structure is established by means of at least one guide peg of the pin and at least one at least partly helically encircling guide groove of the fastening structure.

The electrical device has a closed housing as a protective device, wherein the detachably attached cover of the housing is designed as environmental protection with integrated overpressure protection. The captive central quick-release fastener of the cover simplifies opening and closing the cover and improves accessibility to the interior. In the event of a sudden overpressure, the surface, for example, the entire surface, around the central cover fastening serves as an engagement surface for pressure peaks and pulses. The cover is prevented from deforming in one embodiment by its stiffness. The cover is configured to lift slightly from the housing at the edge to allow pressure peaks to escape. The cover therefore acts as an overpressure protection device and allows sufficient pressure relief. At the same time, the cover is held in place by the central fastening element and furthermore holds back any parts that may become detached from the inside of the electrical device or at least deflects them to the side. In this respect, the cover protects the surroundings of the electrical device against a pressure wave and minimizes the danger to people.

In one embodiment, the cover is attached to the pin of the main body by the centrally arranged cover closure and is not connected to the main body by any other fastening means. It should be appreciated that weak connections between the cover and the housing, for example, adhesive forces of seals at the edge where the cover rests on the side walls, slight tilting or guide hooks are not to be understood in one embodiment as fastening structures. Moreover, the centrally arranged pin which is secured to the rear side of the main body provides optimal accessibility of the interior space of the housing when the cover is open. Since the rotating fastening structure of the cover closure is held in the closure housing, it is ensured that there are no loose parts on the closure during the entire assembly or disassembly of the housing, but that centering, positioning and connecting the cover to the housing can be, in one embodiment, accomplished in one step. This provides a quick-release fastener that is captively installed in the cover, allowing compression of a seal, holding of the cover in the event of an internal failure, and easy positioning of the cover.

When the cover is placed on the housing, the central pin is inserted into the fastening structure, wherein the fastening structure is rotatably and axially non-displaceably retained in the closure housing. In one embodiment, the pin has a cylindrical shape and the fastening structure has a corresponding hollow cylindrical shape for receiving the pin. When the fastening structure is in a central position to receive the pin, the cover is also automatically brought into the correct mounting position with the housing. When inserting the pin into the fastening structure, an outward-facing guide peg of the pin is positioned in a guide groove of the fastening structure. This guide groove is configured to be helical at least in sections, so that the fastening structure is pulled onto the pin during a corresponding rotational movement and thus the cover is also pulled in the direction of the housing. The dimensions of the pin and the fastening structure are matched such that the cover sits firmly on the housing in a predetermined end position and closes it, wherein the connection can also withstand pressures occurring in the interior in the event of a fault. In addition, the central arrangement of the cover closure means that the corners and edge areas of the housing are freely accessible, wherein these areas can comprise, for example, a connection area of the electrical device. This connection area is then largely freely accessible when the cover is open, so that no additional assembly work is required when the device is put into operation.

In one embodiment, the detachable connection can be established by a half-turn or quarter-turn. Such a closure can be easily released by turning it 90 degrees or 180 degrees using a suitable tool. For example, the cover closure can be moved in a simple and defined manner by rotation from a locked closed position to a free open position in which the cover closure is released from the locking pin and the cover can be removed from the housing.

In one embodiment it is advantageous for the locking pin to have a cross peg as a guide peg at its upper end facing the cover. Accordingly, the fastening structure then comprises a helically encircling helix groove comprising two guide grooves for receiving the two ends of the cross peg. This symmetry allows the installation position to be better defined and prevents jamming when the cross peg runs in the helix spiral. In another embodiment, the guide grooves have a latch in an end position. This defines the locked closed position when the guide peg is held in the latch. This prevents the guide peg from accidentally slipping back into the guide groove and thus the cover closure from becoming loose.

In one embodiment, a collar is provided on the closure housing, which forms a stop surface for the cover. This collar defines the installation situation of the closure housing on the cover. The closure housing is, for example, arranged such that it projects through a central opening in the cover and rests with the collar on the outside of the cover, while a fastening acts against the cover from the inside, for example by means of a lock nut. In one embodiment, a first sealing ring is arranged in the collar for sealing between the cover and the closure housing. It is furthermore advantageous for a second seal to act between the fastening structure and the closure housing, for example, using a sealing ring running around the fastening structure. The entire cover structure with a centrally mounted fastening structure and seal is selected such that the electrical device can be operated permanently and safely under all weather conditions and with all electrical parameters.

In order to ensure that the fastening structure is captively held in the closure housing, the fastening structure in an advantageous embodiment comprises a circumferential locking groove and the closure housing comprises a locking pin for engaging in the locking groove, whereby the fastening structure is rotatably and axially non-displaceably retained in the closure housing. The locking groove is, in one embodiment, partially circumferential and thus forms a limitation of the rotational movement of the fastening structure in the closure housing. Alternatively, the locking groove can accommodate a snap ring which prevents axial displacement of the fastening structure in the intended mounting position and ensures that it cannot be lost. A limitation of the rotational movement of the fastening structure can also be realized by additional recesses in the fastening structure, which engage in corresponding elevations in the closure housing.

In order to achieve a better definition of the installation position of the cover and to facilitate the entry of the cross peg of the pin into the helical groove of the fastening structure, the closure housing can comprise axial guide grooves at an end area facing the pin, through which the guide pegs of the pin can be guided to the helically encircling guide grooves of the fastening structure. In addition, a cone that is open towards the cover can be arranged around the end area of the pin, which provides additional relief for central positioning during cover assembly.

In one embodiment, the cover closure has markings to indicate the installation position and/or to indicate an open position and closed position. This is achieved in one embodiment by a visually recognizable indicator, which can be formed, for example, by different colors or different symbols.

In one embodiment of the housing, the cover has a sealing surface that extends essentially in one plane. The cover then rests with the sealing surface on the edges of the side walls of the main body. It goes without saying that the side walls may be formed by a single component; in this respect, housings having a round rear wall and a correspondingly continuous side wall are also included. A circumferential seal can be arranged between the rims of the side walls of the main body and the cover. A pressure force is exerted on the seal by the cover closure via the cover so that the housing can be closed tightly. As a result, a degree of protection of the interior of the housing can be ensured of at least IP54, for example, at least IP65 and/or NEMA type 4X.

The entire cover structure with a centrally mounted fastening structure and seal is selected such that the electrical device can be operated permanently and safely under all weather conditions and with all electrical parameters. For this purpose, the cover stiffness, for example, is designed such that the cover is, on the one hand, stiff enough to transfer a contact force from the central cover closure via the cover surface to the edge and thus to the seal in such a way that the seal experiences the necessary compression force. At the same time, the cover has such optimized stiffness that it can deform all around the centrally mounted screw when a certain internal pressure is reached. This creates an optimized opening area for pressure relief and the pressure escapes slowly. In addition, the overall load on the cover closure is reduced in the event of an explosion, so that the cover does not tear off at the cover closure.

The housing according to the disclosure can particularly advantageously accommodate power electronic components in the interior. These include in particular switches, capacitors and/or inductors that are suitable for converting electrical power within the device. In particular, the housing can accommodate a power converter, in particular a rectifier, an inverter and/or a DC/DC converter. Especially in the area of power converters with nominal power in the range of several tens to several hundred kilowatts, technical progress brings with it increases in power density, which at the same time exacerbate the problem of unwanted energy accumulation explained above and therefore require housings adapted to the correspondingly increasing risk.

In the event of overpressure occurring inside the housing, in particular in the event of a sudden overpressure such as may occur in a high-power electrical device, the cover may detach from the edges of the side walls on all sides and undergo plastic deformation. This allows pressure to be reduced in all directions. Moreover, the plastic deformation leads to a relief in the cover closure, since the surface area over which the overpressure acts decreases due to the deformation of the cover. Due to the rapid pressure reduction, the tensile force acting on the cover closure is quickly reduced. The overpressure can also be relieved by elastic deformation of the cover, so that in the event of overpressure the cover lifts off the side walls and releases a pressure relief opening, which closes again after the pressure has been relieved.

### BRIEF DESCRIPTION OF THE FIGURES

The disclosure is further explained and described below with reference to example embodiments illustrated in the figures.

FIG. 1 shows an embodiment of an apparatus according to the disclosure;

FIG. 2 shows the cover closure of an embodiment of the apparatus according to the disclosure;

FIG. 3 shows a sectional view of the cover closure of the embodiment of the apparatus according to the disclosure;

FIG. 4 shows the cover fastening of the closure housing;

FIG. 5 shows the cover closure indicator; and

FIG. 6 schematically shows the positions of the cover closure.

### DETAILED DESCRIPTION

An electrical device within the meaning of this disclosure processes electrical power, in particular by converting electrical currents from one form to another, for example from direct current to alternating current or vice versa, or by deliberately changing essential properties of the electrical power, for example the voltage or the frequency. In particular, the device can be an electronic power device, i.e., a power converter, in which circuit breakers are arranged in a converter topology and interact with capacitors and inductors.

During operation of an electrical device of this kind, the voltages and currents applied to the terminals of the power converter are influenced in a targeted manner by suitable clocking of the circuit breakers. Considerable electrical power can flow through the electrical device and be exchanged between the devices connected thereto. For example, an energy source, in particular a power supply network, a generator or a battery, can be connected via a power converter in a housing according to the disclosure to an energy sink, in particular to a load, a battery or to a (further) power supply network.

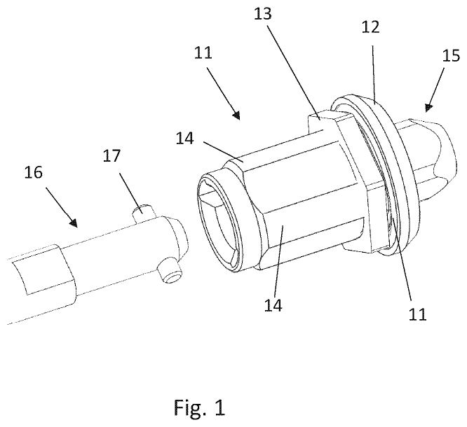

FIG. 1 shows a cover closure according to the disclosure. The housing (not shown) comprises a main body. The main body can be formed in one piece, for example, as a die-cast part, or be composed of several parts, for example, a rear wall and side walls. In principle, in one embodiment the main body can have a substantially rectangular layout, so that it comprises four substantially flat side walls, or a round or oval layout, so that it essentially has one circumferential side wall.

The housing comprises a cover. The main body and the cover form a closed interior of the housing, with the cover being placed in a form-fitting manner on the edges of the side walls of the main body. Any openings in the side walls and/or the rear wall of the main body, for example, for cable ducts, can be made with suitable seals.

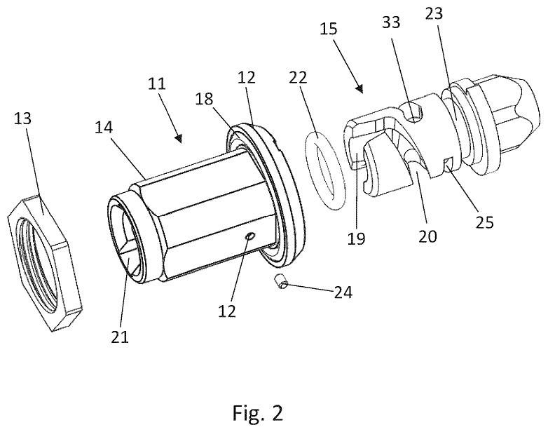

The cover is detachably connected to the main body by means of a central cover closure. According to FIG. 1, the cover closure comprises a closure housing 11 which is fixed to the cover (not shown) by means of a collar 12 designed as a stop surface and a lock nut 13 which also serves as a grounding nut. The closure housing 11 has an essentially rotationally symmetrical or cylindrical basic shape. An external thread 14 can be provided on the peripheral surface, onto which the lock nut 13 can be screwed. To attach the closure housing 11 to the cover, the closure housing 11 is guided through an appropriately dimensioned opening in the cover until the collar 12 rests against the outside of the cover. The closure housing 11 is then fixed to the inside of the cover with a lock nut (not shown). The opening of the cover is, in one embodiment, located in the geometric center of the cover. The closure housing 11 is designed in one embodiment as a hollow cylinder so that it can accommodate a fastening structure 15 (see also FIG. 2). The fastening structure 15 is also designed in one embodiment as a hollow cylinder to match the cavity of the closure housing 11, so that the fastening structure 15 can be inserted into the closure housing 11, for example, from the outside of the cover. The fastening structure 15 is held in the closure housing 11 in an axially rotatable but captive manner, i.e., in an axially non-displaceable manner. To create the closure connection between the cover and the main body of the housing, a rod-shaped closure pin 16 is in one embodiment provided which extends from the rear wall of the housing to the opening of the cover. At the end of the pin 16 directed towards the cover, the pin has a cross peg 17 which extends radially outward on two opposite sides of the pin 16. The cross peg 17 usually comprises a peg that is inserted through a bore with a fit in the pin 16 and aligned centrally. The pin 16 with the cross peg 17 is part of the housing rear wall and is firmly installed therewith, wherein the housing rear wall can also include additional structural reinforcements in this area in order to better withstand the tensile forces acting on it. The pin 16 with the cross peg 17 is dimensioned such that it can be inserted into the fastening structure 15 and can be received therein.

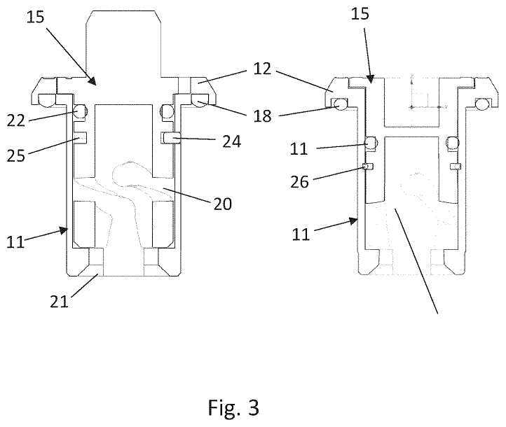

In FIG. 2, the cover-side closure components are shown in an exploded view. The closure housing 11 with the lock nut 13, as in FIG. 1, and the fastening structure 15 can be seen. The closure housing 11 has a collar 12 which, as described, serves as a stop surface for the outside of the cover. A seal 18 is arranged in the collar 12, which seals the closure housing 11 against the cover when mounted and thus protects the interior from environmental influences such as moisture and dust. This seal 18 can be designed in a known manner, for example, as a rubber sealing ring or as a foam bead. The fastening structure 15 comprises a receptacle 19 for the closure pin 16, wherein the inner diameter of the receptacle 19 is adapted to the outer diameter of the closure pin 16. Furthermore, the fastening structure 15 comprises a helical groove comprising two helically encircling guide grooves 20. These guide grooves 20 are configured to receive the cross peg 17 of the pin 16. In the embodiment shown, the guide grooves 20 penetrate the shell of the fastening structure 15. However, it is also conceivable in one embodiment for the shell of the fastening structure 15 to be closed and for the guide grooves 20 to be formed only on the inside. From a manufacturing point of view, however, the fully penetrating guide grooves 20 are much easier to implement. In the initial area of the receptacle 19, the guide grooves 20 may be aligned not helically but axially. This facilitates the insertion of the cross peg 17 and the correct positioning of the entire cover. The closure housing 11 can also have a corresponding guide section 21 at its end facing the pin 16. Sealing of the fastening structure 15 against the closure housing 11 can be realized by a further seal 22 which, in the assembled state, is arranged in a circumferential sealing groove 23 of the fastening structure 15. Integrating the seals 18, 22 in the cover closure, which is permanently mounted on the cover in one embodiment, ensures that tightness is not lost even when the cover is disassembled and reassembled on the housing main body, so that a new seal does not have to be used each time. A locking pin 24 is pressed into a hole 24a of the closure housing 11 for axially securing the fastening structure 15, which locking pin 24 engages in a semi-circumferential locking groove 25 of the fastening structure 15. This secures the fastening structure 15 against falling out and at the same time establishes a rotation restriction, in this case half a turn. But this can also be achieved in other ways. For example, the locking groove 25 of the fastening structure 15 can be completely circumferential and accommodate a snap ring 26 (see FIG. 3) which, in the correct position, springs into a corresponding locking groove of the closure housing 11. Axial securing and the position of the seals 18, 22 can be seen in the sectional view of FIG. 3, which shows the closure housing 11 with the accommodated fastening structure 15.

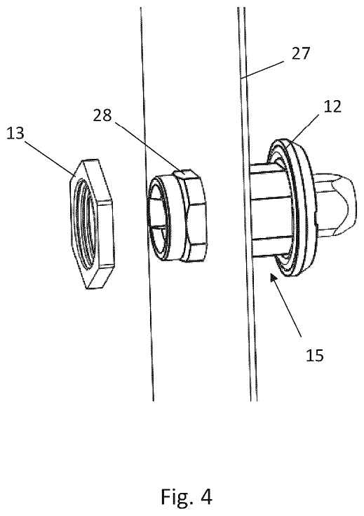

The assembly of the closure housing 11 on the cover 27 is shown in FIG. 4. The closure housing 11 is mounted in a central opening of the cover 27 with the stop surface of the collar 12 and the lock nut 13, which also serves as a grounding nut. In one embodiment, the cover opening is not circular, but for example square with rounded corners. The outer surface of the closure housing 11 in one embodiment has flattened portions 28 adapted to the opening, so that the closure housing 11 can be fixed in a rotationally secure manner. This allows the cover closure to be precisely aligned with the cross peg 17 of the pin 16.

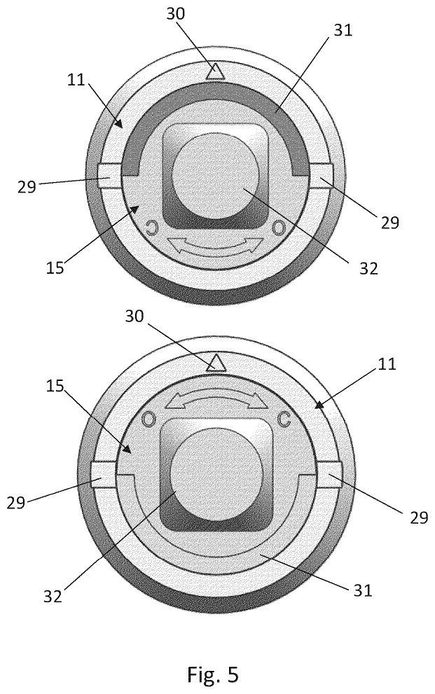

FIG. 5 shows one embodiment in which various markings are provided on the closure housing 11. Two opposing markings 29 are provided for correct positioning of the cover closure over the central pin. They can be formed, for example, by color markings or structural markings (elevations, notches, etc.). These markings 29 are intended to ensure correct installation. For a central cover closure, the pin 16 should be installed such that the cross peg 17 is in a horizontal position. The closure housing 11 is then installed such that the side markings 29 are also horizontal. This simplifies the positioning and installation of the cover, especially in the case of multi-symmetrical or circular housing shapes. In addition, in FIG. 5, the triangular marking 30 indicates the installation direction up or down, depending on which view is preferred for the “open” and “closed” positions. Additional markings may indicate the direction of rotation; for example, in the embodiment shown, arrows and letters indicate the direction of rotation for the open position (O) and the closed position (C for “closed”). A color marking 31 on the closure housing additionally enables an optical position indication, in which, for example, the visible part of the color marking shows green in the closed position (FIG. 5, bottom) and, after half a rotation of the central fastening means 15, shows red in the open position (FIG. 5, top).

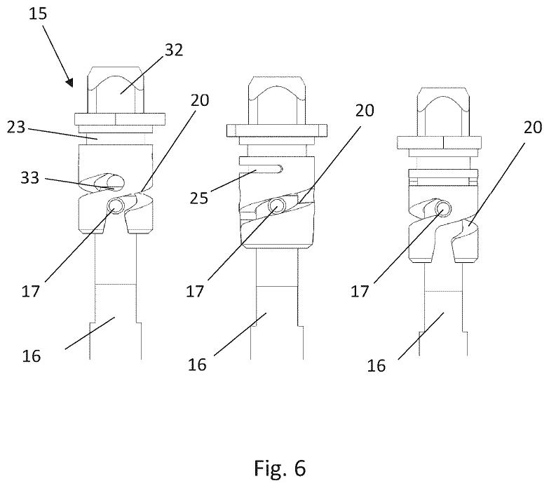

The functionality of the cover closure is illustrated in FIG. 6, where the interaction of the fastening structure 15 with the locking pin 16 when closing the cover is shown. On the left the situation is shown with the cover on, in the middle with the cover half closed, and on the right with the cover closed. The fastening structure 15 is constructed such that a rotational movement is converted into a translational movement. For this purpose, the double-sided helix groove 20 is introduced into the fastening structure 15. It represents the path of movement into which the cross peg 17 engages. When turning the actuator 32, the cover connected to the closure is moved downwards. The distance traveled in the direction perpendicular to the cover plane is, in one embodiment, sufficient to compress the seal and compensate for the deformation of the cover. Since this force can be considerable even for medium-sized covers due to the central insertion, the path is set to a 180° rotation in one embodiment. To allow for the same vertical movement of the cover, for example, a quarter turn would require half the rotation distance but twice the force. If a larger compression path is required, e.g., because of a larger seal, the path can also be increased. This would correspond to a “stretched out” helix. However, in that case one would have to consider that the actuation force will increase again because the starting angle becomes steeper. Specific angles of rotation between 90° and 180° can also be realized and the compression path can be specifically adjusted within certain limits. The system is also scalable in size. Both right- and left-closing variants are possible. In case of central closure solutions, the necessary closing force depends heavily on the size of the cover and the necessary compression force of the seal. In case of small covers, a quarter-turn may be sufficient. For larger covers, a half-turn offers a longer inlet path and therefore a lower closing force. At the end of the track, a latch 33 is provided on both sides, here in the form of a track recess. The cross peg 17 has its end position here and is held there securely by the tensile force exerted by the cover and seal. In the event of an explosion, the cover closure holds the cover securely on the main body of the housing.

What is claimed is:

1. A housing of an electrical device configured to convert electrical power, wherein the housing comprises a main body with a rear wall and side walls and a cover, wherein the cover closes the main body so that a self-contained interior space is created, wherein electrical and electronic components of the electrical device are arranged in the interior space of the housing, wherein the cover is detachably connected to the main body by a cover closure,
wherein the cover closure comprises a fastening structure and a closure housing,
wherein the fastening structure is rotatably and axially non-displaceably retained in the closure housing,
wherein the closure housing is fastened to the cover in a geometric center of the cover,
wherein the main body comprises a pin that extends from the rear wall of the housing to the geometric center of the cover,
wherein a connection between the cover and the pin is releasable by turning the fastening structure established by at least one guide peg of the pin and at least one at least partly helically encircling guide groove of the fastening structure.

2. The housing according to claim 1, wherein a detachable connection between the cover and the pin is established by a half-turn or quarter-turn.

3. The housing according to claim 1, wherein the pin comprises a guide peg configured as a cross peg comprising two ends, and the fastening structure comprises an at least partly helically encircling helix groove comprising two guide grooves configured to receive the two ends of the cross peg.

4. The housing according to claim 3, wherein the guide grooves comprise a latch in an end position.

5. The housing according to claim 1, wherein the closure housing comprises a collar which forms a stop surface for the cover and in which a first seal is arranged for sealing between the cover and the closure housing.

6. The housing according to claim 5, wherein a second seal for sealing between the fastening structure and the closure housing is arranged circumferentially around the fastening structure.

7. The housing according to claim 1, wherein the fastening structure comprises a circumferential locking groove and the closure housing comprises a locking pin configured to engage the circumferential locking groove, whereby the fastening structure is rotatably and axially non-displaceably retained in the closure housing.

8. The housing according to claim 7, wherein the locking groove is partially circumferential and thus forms a limitation of a rotational movement of the fastening structure in the closure housing.

9. The housing according to claim 1, wherein the fastening structure and the closure housing each comprise a circumferential locking groove in which a snap ring is arranged, whereby the fastening structure is rotatably and axially non-displaceably retained in the closure housing.

10. The housing according to claim 1, wherein the closure housing comprises axial guide grooves at an end area facing the pin to define an installation position, through which at least one guide peg of the pin is guided to the at least partly helically encircling guide grooves of the fastening structure.

11. The housing according to claim 9, wherein the cover closure comprises markings to indicate an installation position, or to indicate an open position and a closed position, or both.

12. The housing according to claim 1, wherein the cover is attached to the main body exclusively by the centrally arranged cover closure and is not connected to the main body by any other fastening devices.

13. The housing according to claim 1, wherein the cover has a sealing surface that extends in one plane, with which the cover rests on edges of the side walls of the main body.

14. The housing according to claim 12, further comprising a circumferential seal arranged between edges of the side walls of the main body and the cover, onto which a compressive force is exerted by the cover closure via the cover, so that the housing is closed tightly such that a degree of protection of an interior of the housing can be ensured of at least IP54.

15. The housing according to claim 1, wherein components in an interior of the housing comprise power electronic components configured to convert electrical power within the electrical device.

16. The housing according to claim 1, wherein the cover is configured to lift off from the edges of the side walls on all sides and is plastically deformed so that a pressure reduction in all directions is made possible in the event of an overpressure occurring in an interior of the housing.

17. An electrical device comprising the housing according to claim 1.
